(19) United States
(12) Patent Application Publication
(10) Pub. No.: US 2025/0112660 A1
(43) Pub. Date: Apr. 3, 2025

(54) BIDIRECTIONAL LINK WITH HYBRID SUPPRESSION CIRCUIT

(71) Applicant: Intel Corporation, Santa Clara, CA (US)

(72) Inventors: Horaira ABU, Fremont, CA (US); Harry MULJONO, San Ramon, CA (US); Gerald S. PASDAST, San Jose, CA (US)

(21) Appl. No.: 18/375,348

(22) Filed: Sep. 29, 2023

(51) Int. Cl. H04B 1/38; H03K 5/1252

(52) U.S. Cl. CPC H04B 1/38; H03K 5/1252

(57) ABSTRACT

In some embodiments, an interconnect with a plurality of single-ended, bi-directional channels capable of simultaneous bi-directional data transfer is provided. There may be Tx/Rx circuits, each having a suppression circuit, on each side of a channel with each being capable of operating at independent supply levels and clock frequencies.

### TECHNICAL FIELD

Embodiments of the invention relate to the field of integrated circuit communication links; and more specifically, to bidirectional links for communications between integrated circuit dies.

### BRIEF DESCRIPTION OF THE DRAWINGS

The invention may best be understood by referring to the following description and accompanying drawings that are used to illustrate embodiments of the invention. In the drawings:

FIG. 1A is a block diagram of a conventional two-channel bi-directional link.

FIG. 1B is a block diagram of a conventional single-channel bi-directional link.

FIG. 2 is a high level block diagram of a bi-directional, single-channel link in accordance with some embodiments.

FIG. 3A is a schematic of a transmitter with a suppression circuit for use with a transmitter/receiver (Tx/Rx) circuit in accordance with some embodiments.

FIG. 3B is a signal diagram showing suppression operation for the circuit of FIG. 3A in accordance with some embodiments.

FIG. 4 shows a link with suppression circuitry for a single D2D channel in accordance with some embodiments.

FIGS. 5A and 5B show an exemplary multi-chip IC package with first and second dies coupled together through die-to-die blocks in accordance with some embodiments.

FIG. 6 is a schematic diagram showing a bi-directional channel link with a suppression circuit in accordance with some embodiments.

FIG. 7 is a schematic diagram showing yet another bi-directional channel link with a suppression circuit in accordance with some embodiments.

FIG. 8 illustrates an example computing system that incorporates one or more D2D links in accordance with embodiments disclosed herein.

FIG. 9 illustrates a block diagram of an example processor and/or SoC 900 that may be used in the system of FIG. 8 in accordance with some embodiments.

### DETAILED DESCRIPTION

With today's integrated circuits (ICs), it is common for multiple dies (also referred to as chips, chiplets, or dielets) to be integrated into a common IC package. With such multi-die packages, short reach die-to-die (D2D) interfaces are typically used to communicatively couple some or all of the dies to each other.

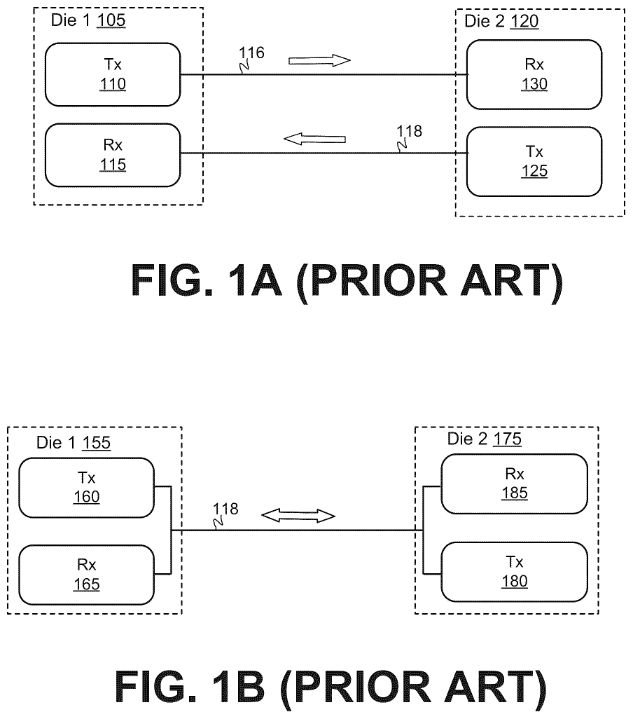

FIG. 1A is a high-level conceptual diagram showing a single-ended, bi-directional two-wire channel in a D2D link that may include hundreds or even thousands of other channels in the link. Each channel includes a transmitter (Tx) and receiver (Rx) link pair (110< >130) and (125< >115) to transfer bits of data in each direction. They are implemented with separate wires (116, 118) to couple together each Tx/Rx pair between the dice, for example, using a source synchronous clocking scheme for data synchronization. The use of separate unidirectional tracks for the bidirectional channel allows each die to operate at its own clock frequency. However, with newer IC design generations, bandwidth demand for D2D interfaces is ever-increasing, requiring more and more die shoreline to facilitate the additional channels needed to provide the increased bandwidth.

With this in mind and with reference to FIG. 1B, full duplex transmission schemes using only a single channel have been employed. As seen in the figure, the complementary Tx< >Rx link pairs (160< >185, 180< >165) share a common wire (also referred to as track or line) for providing data transfers in both directions over the single wire 118. For example, DC coupled bidirectional schemes have been implemented where both dies operate at the same clock frequencies, with the clocks on both sides being synchronized with one another. Unfortunately, such links typically have to operate at lower frequencies due to frequency drift and physical circuit parameter variations. In addition, the Tx and Rx circuits on both sides generally have to operate at the same supply voltages or at least be able to exchange supply information across the channel. Accordingly, in some embodiments, links may be provided that employ circuits to facilitate simultaneous communications in both directions (full duplex) over a single track (or wire), and in some of these embodiments, each side may operate at independent supply levels and/or at independent transfer clock frequencies.

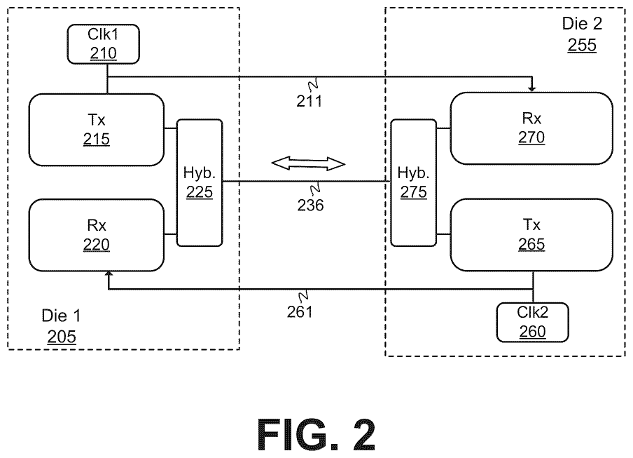

FIG. 2 is a high level block diagram of a single D2D channel link in accordance with some embodiments. Each die (205, 255) includes a transmitter (215, 265) and a receiver (220, 270) coupled together through a suppression (sometimes referred to as hybrid) circuit (225, 275) to communicate with the other die through a single wire 236. Each die also has a Clk circuit (210, 260) to provide a clock to its own transmitter, as well as to its associated receiver on the other die over a clock wire (211, 261). Clock circuits may use any suitable configurations to generate clocks for their associated transmitter circuit blocks, as well as for their clocks that are forwarded to receivers on the other side of a link. For example, they may include dedicated phase locked loops (PLLs) or circuitry such as clock synthesis, divider/multiplier, and/or buffer/driver circuitry for deriving and/or distributing clock signals from other PLLs or clock generation sources. (Note that while only a single data channel 236 is shown, there may actually be multiple channels, e.g., tens to hundreds of data lines for each of the two clock lines, and thus, a relatively small number of overall wires are needed for a full duplex, multi-channel link implementation.)

With the depicted DC coupled, full duplex implementation, each die is allowed to transmit data at its own clock data rate. There isn't a requirement to align the clocks between the two dies. The signal on a data line 236 includes a superimposed waveform from the transmitted signals from both dies. The suppression circuitry (225, 275) operates to effectively extract the signal coming from the other side of the channel and provide it to its associated receiver. As it is doing so, it suppresses the transmitted signal from its own side, allowing its receiver to more cleanly receive the signal from the other die.

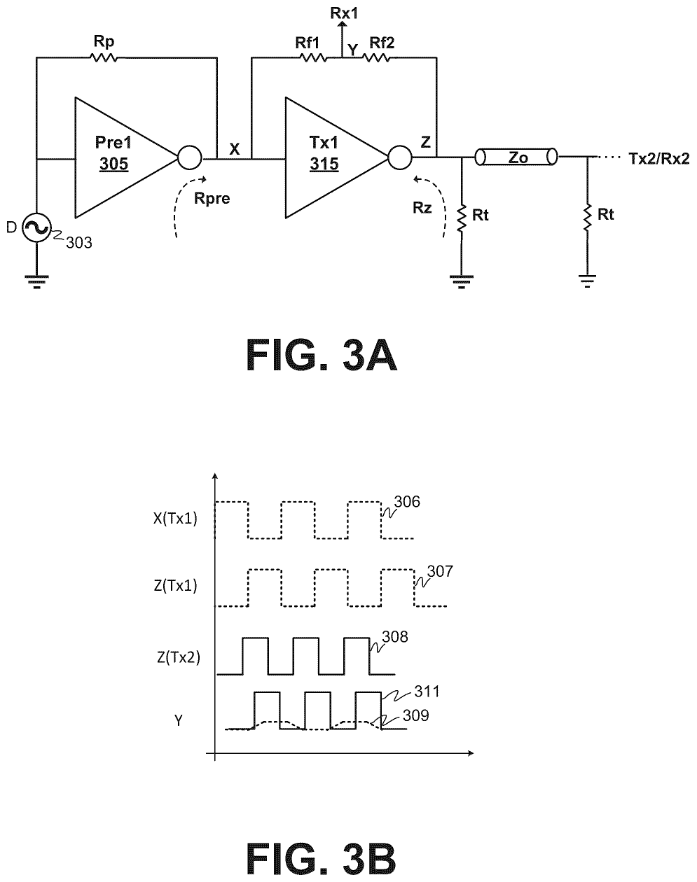

FIG. 3A is a schematic of a transmitter with a suppression circuit for use with a Tx/Rx circuit in accordance with some embodiments. The circuit includes a transmitter with incorporated suppression circuitry to suppress, the transmitted data (D) from data generator 303 at the receiver (Rx1) node, labeled as “Y”. The transmitter includes an inverting pre-driver (Pre1) 305, which has a feedback resistor (Rp) that improves the transition time at the driver input. The transmitter also has a transmitter driver circuit 315, which receives data from the pre-driver output (labeled as “X”). The Tx driver 315 has a feedback resistance formed from two feedback resistors (Rf1, Rf2) connected as shown from the driver output (Z) to its input (X). The feedback resistors enable it to act like a trans-impedance amplifier Voltage mode driver, which provides less output impedance variations across the full range of pad voltage values. There is a pre-driver resistance (Rpre) as seen from the transmitter driver input (X). This pre-driver resistance (Rpre) is composed of the output impedance of the pre-driver 305 in parallel with the pre-driver feedback resistor Rp. There is also an output impedance (Rz) as seen from the transmitter driver output (Z). Rz is essentially made of channel line resistance, along with any termination resistors (Rt) that may be used on the channel. Note, however, that with many short reach channels, such as are commonly used with D2D implementations, termination resistors are in many cases not employed.

With this configuration, under ideal conditions, when Rz is equal to Rpre, the suppression circuit “bridge”, formed from Rp, Rf1, Rf2, and Rz, may be said to be “balanced”, which serves to suppress transmitter signal components from nodes X and Z at the receiver input node (Y). Thus, the receiver circuit can receive data from the other side of the link (Tx2) over the channel without undue interference from its own transmitting signal.

FIG. 3B is a signal diagram illustrating suppression operation for the circuit of FIG. 3A in accordance with some embodiments. The generated signal 306 for Tx1 is provided at the output (X) of pre-driver circuit 305. The transmitter driver 315 receives this signal and generates an inverted version 307 at its output Z. At the same time, a signal 308 is received from Tx2 on the other side of the channel. At the Rx1 input (Y), it can be seen that the signal 309 generated from Tx1 is substantially suppressed while the Tx2 signal 311 remains for reception by Rx1. However, a small portion 309 of the transmitted Tx1 signal does end up at the Rx1 input node (Y). Due, among other things, to finite delay from the pre-driver to the driver output, the signal suppression is not perfect, which can result in glitches on the line. Accordingly, in some embodiments, techniques are provided below to better tune suppression circuitry for improved operations.

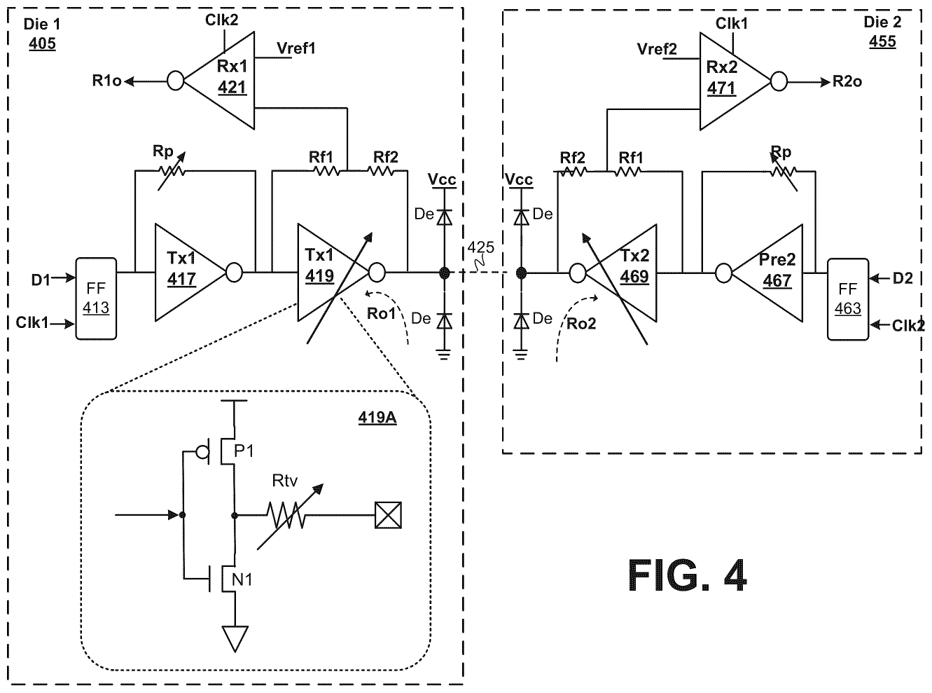

FIG. 4 shows a link with suppression circuitry for a single D2D channel in accordance with some embodiments. Each of first die 405 and second die 455 has a Tx/Rx circuit for communicating with the other die's Tx/Rx circuit over channel line 425. In this implementation, the Tx/Rx circuits on either side are equivalent and thus for brevity sake, only the circuitry for die 405 will be discussed with the understanding that the description applies to the circuitry on die 2 as well.

The Tx1/Rx1 circuitry includes a data transfer flop 413, a transmitter pre-driver 417, a variable transmitter driver 419, and a receiver Rx1 421, all coupled together as shown. Also included is a/suppression circuit formed using variable resistor Rp and driver feedback resistors Rf1, Rf2. (Note that the clock lines for Clk 1 and Clk 2 have been omitted for clarity.)

The data flip-flop 413 acts as a synchronizer to clock data (D) through Tx1 based on an applied first clock (Clk1). While a flip flop is shown, it should be appreciated that any suitable sequential circuit could be used for clocking and/or buffering data to the Tx1 pre-driver.

In the depicted embodiment, the Tx1 pre-driver 417 is implemented with an inverter such as a P/N inverter, an inverter formed from N-type and P-type transistors with their gates and drains coupled together. However, it should be appreciated that inversion at the pre-driver is not required. Any suitable pre-driver circuitry amenable to tuning to match the output resistance Ro1 (resistance seen from the output of the Tx1 driver 419) would suffice. Along these lines, the resistor used for pre-driver feedback in this embodiment is a variable resistor Rp, which allows for the pre-driver resistance (Rpre) to be tuned to match particular channel resistance parameters. For example, in this implementation, the channel in addition to including wire 425 also includes electro-static discharge (ESD) diodes De at the pads on either side of the channel wire 425. Note also that in this embodiment, termination resistors are not used, for example, this may be used in a short reach D2D link. It is noted that the omission of termination resistors can actually make it more challenging for matching channel (output) resistance to pre-driver feedback resistance because when termination resistors are used, they typically dominate the output resistance thereby making it more predictable, not as dependent on the particular characteristics of the line and Tx/Rx circuitry from the other die.

In the depicted embodiment, the Tx1 driver 419 is implemented with a variable strength driver such as the variable strength inverter shown at 419A, which allows for additional suppression circuit tuning. Likewise, feedback resistors Rf1, Rf2 are used as transmitter driver feedback resistors for the suppression circuit. In an ideal implementation, they would be equal to one another, but with practical implementations, they may be different to adjust for specific delays and circuit characteristics related to the transmitter and channel components.

The die 1 transmitter (Tx1) operates at a Clk1 frequency, while the die 2 transmitter (Tx2) operates at a second (Clk2) frequency. These clocks can be generated by different clock generation circuits from their respective dies, and there need not be a phase or frequency relationship expectation between the clocks. In addition, the frequencies for Clk1 and Clk2 can be the same, or they may be different. Likewise, the power supplies for each die can also vary independently.

The receiver 421 samples the received signal using the forwarded clock (Clk2) from die 2. In some embodiments, the receiver is implemented using a strong-arm comparator latch. The Voltage reference level (Vref1) for the receiver may be derived from its power supply, which as already mentioned, may be different from that of the other die's Tx/Rx supply level. In some embodiments, Vref may be fixed, set during manufacture, or set at circuit power-up, ideally, to be centered at a received data eye for maximum voltage margin. In this way, each die can be operated not only at different frequencies, but also, they may be powered at the different supply levels.

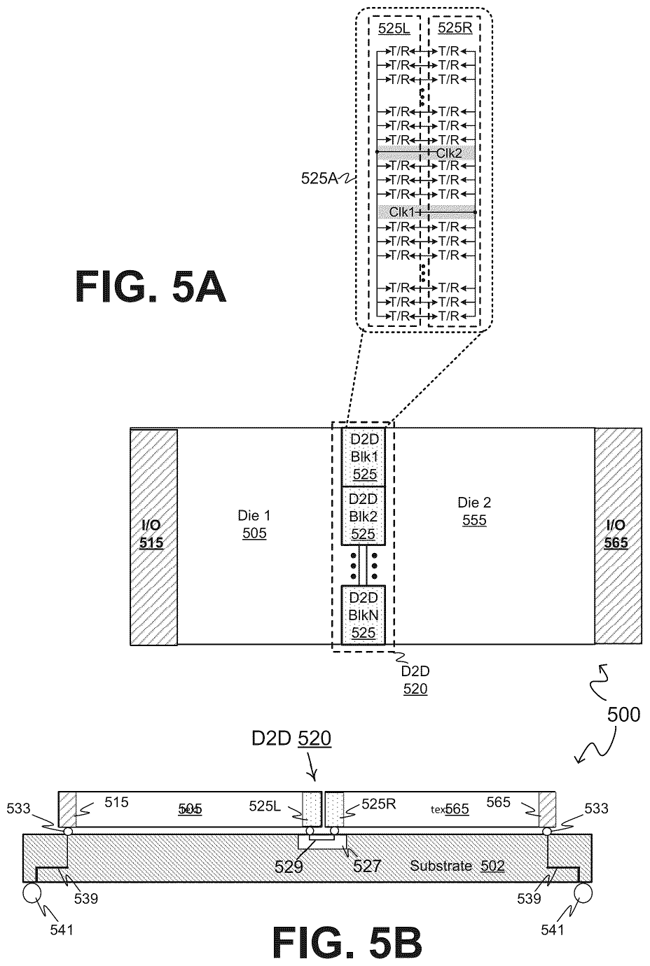

FIGS. 5A and 5B show an exemplary multi-chip IC package with first and second dies coupled together through D2D blocks in accordance with some embodiments. FIG. 5A is a top schematic view of IC package 500, while FIG. 5B is a side cross-sectional view of the IC package. Package 500 includes first and second dies (505, 555) communicatively coupled together through N D2D blocks 525.

In the depicted embodiment, an exemplary D2D block 525A is shown. The block generally includes a multiplicity (e.g., 50 to 100) transmitter/receiver (Tx/Rx) circuits 525L on die 1 coupled to counterpart Tx/Rx circuits 525R on Die 2. Also included in the block are forwarded clocks (Clk1, Clk2) indicated by the shaded regions. Each of the Tx/Rx circuits may be implemented with suppression circuitry as described herein. It can be seen that with multiple blocks of such Tx/Rx< >Tx/Rx channels, thousands, or more, fully duplexed D2D channels each using a single wire may be achieved. Also shown are I/O sections 515, 565 for providing off-chip transceiver interfaces, e.g., for DDR or PCIe links outside of the IC package.

The D2D Tx/Rx circuits may be coupled to their counterpart circuits on the other die through D2D wires, traces, or any suitable structure. For example, as shown in FIG. 5B, they may be coupled together through wires 520 that are embedded within a bridge 527, which in this example, are disposed in a multi-chip substrate 502. The D2D block sections are aligned next to each other, which allows for them to be coupled together using the bridges. Likewise, the I/O blocks 515, 565 are disposed on the outside edges (outer edge of Die 1 and outer edge of Die 2), making them accessible for off-chip communications. In this example, the I/O and D2D sections may be coupled to the bridges and/or to contacts on the substrate through micro-bumps 533 (e.g., with pitches in the neighborhoods of 40 microns). In turn, any or some of these connections may be brought off-package through substrate wires 539 and package bumps 541.

It should be appreciated that any suitable structures may be used for connecting dies to each other through Tx/Rx< >Tx/Rx channels as described herein. For example, wafer-level fan-out redistribution, using reconstituted wafer substrates of molding compounds as the surface for interconnections between dies may be used in 2D or 2.5D implementations. Similarly, with some methods, a separate, usually silicon-based, interconnect layer for redistribution could be used. For example, either an interposer (passive and/or active, typically formed from silicon) or die-to-die bridges (e.g., such as silicon bridges as shown in FIG. 5B) embedded in an organic surface (e.g., substrate surface or interposer) could be employed.

An interposer is typically formed from a piece of silicon, large enough to accommodate the multiple chips with the chips being bonded to the interposer. Interposers typically include multiple signal lines (e.g., data and clock lines), and because the data is being moved from silicon to silicon, the loss of power may be minimized.

Bridges, such as EMIB (Embedded Multi-Die Interconnect Bridge), developed by Intel Corp., may also be employed. EMIB is an example of a 2.5D MCP bridge interconnect technology. In some forms, EMIB may be a combination of both interposer and substrate. Rather than simply employing a large interposer, this technique may use a small slither of silicon (the bridge) embedded into the substrate. Such a bridge may include hundreds or thousands of connections to couple adjacent sides of two chips together. In this way, data between the chips may be transferred through silicon without excessive restrictions. Also, multiple bridges between two chips may be employed if more bandwidth is needed, or multiple bridges for designs using more than two chips could also be used.

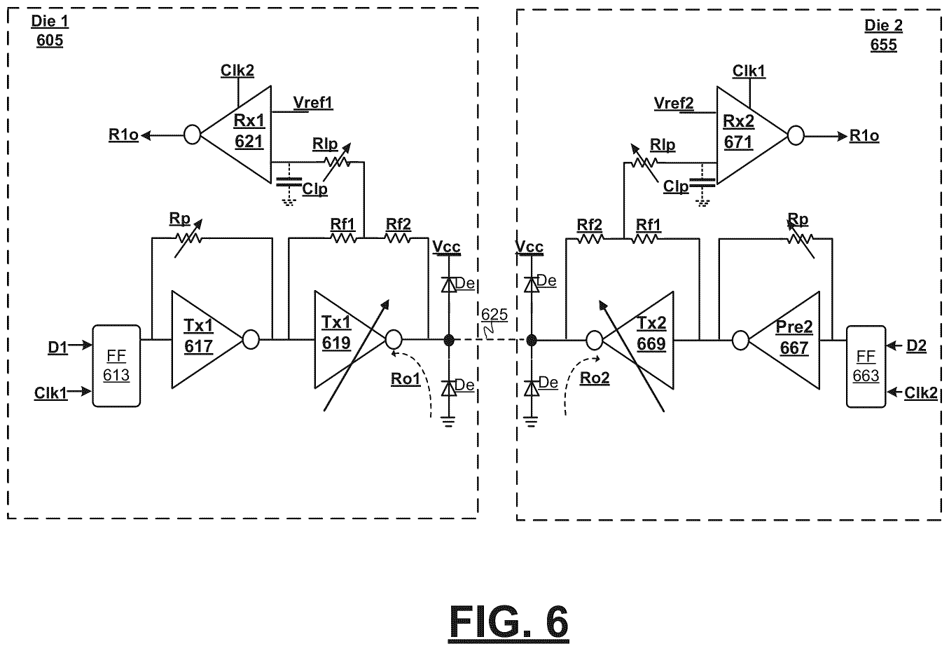

FIG. 6 is a schematic diagram showing a bi-directional Tx/Rx< >Tx/Rx channel link with suppression circuitry in accordance with some embodiments. The suppression circuitry is similar to the circuitry of FIG. 4 except that it includes a low-pass filter at each of the inputs to the receivers 621, 671. Each of these filters is formed from a resistor (R1p), variable in the depicted embodiment, and parasitic gate capacitances that are inherent to the receiver inputs. The low pass filters serve to clean up unwanted data glitches to leave the received signal from the other die to be sampled and resolved by the receiver. accordingly, the filters should have cut-off frequencies for sufficiently passing the received signals from the other die.

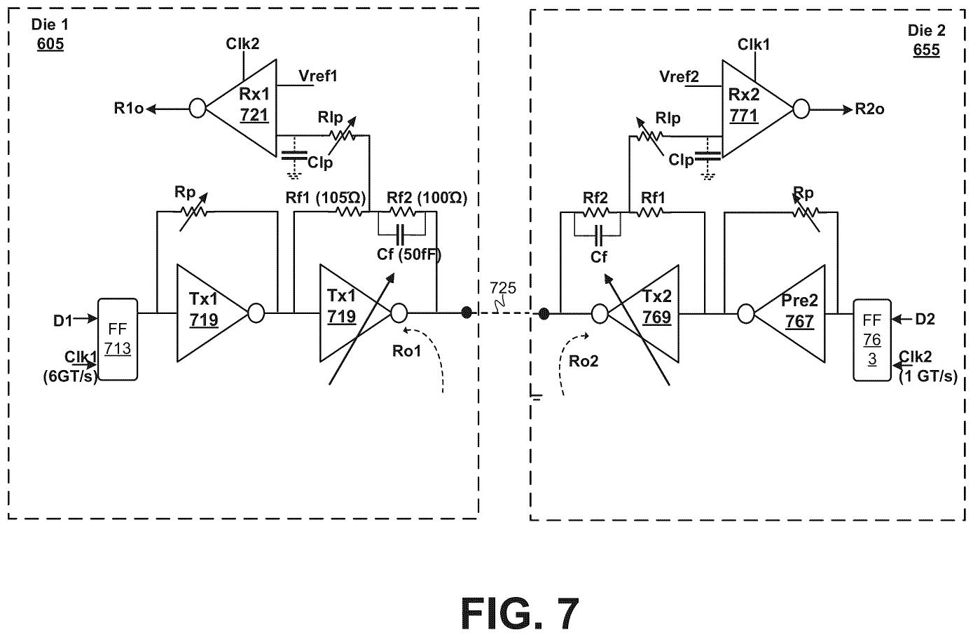

FIG. 7 is a schematic diagram showing yet another bi-directional Tx/Rx< >Tx/Rx channel link with a suppression circuit in accordance with some embodiments. The suppression circuitry is similar to the suppression circuitry of FIG. 6 but in addition, it includes a small capacitor (Cf) coupled in parallel across one of the transmitter driver feedback resistors, resistors Rf2 in this depiction, for transmitters on either side of the channel. In addition, exemplary resistor and capacitor values are also included.

In some embodiments, the transmitter drivers (Tx1, Tx2) are set to be compensated to match the line resistances (Ro1, Ro2). In the depicted embodiment, die 1 is operating at a 6 GHz data transmission rate while die 2 operates at a 1 GHz data transmission rate. In addition, the power supply of die 1 (Vcc1) is at 1 v while the die 2 power supply (Vcc2) is at 0.7 V. In some embodiments, during initial power on, the reference voltage for each receiver can be set based on a received signal data eye through training.

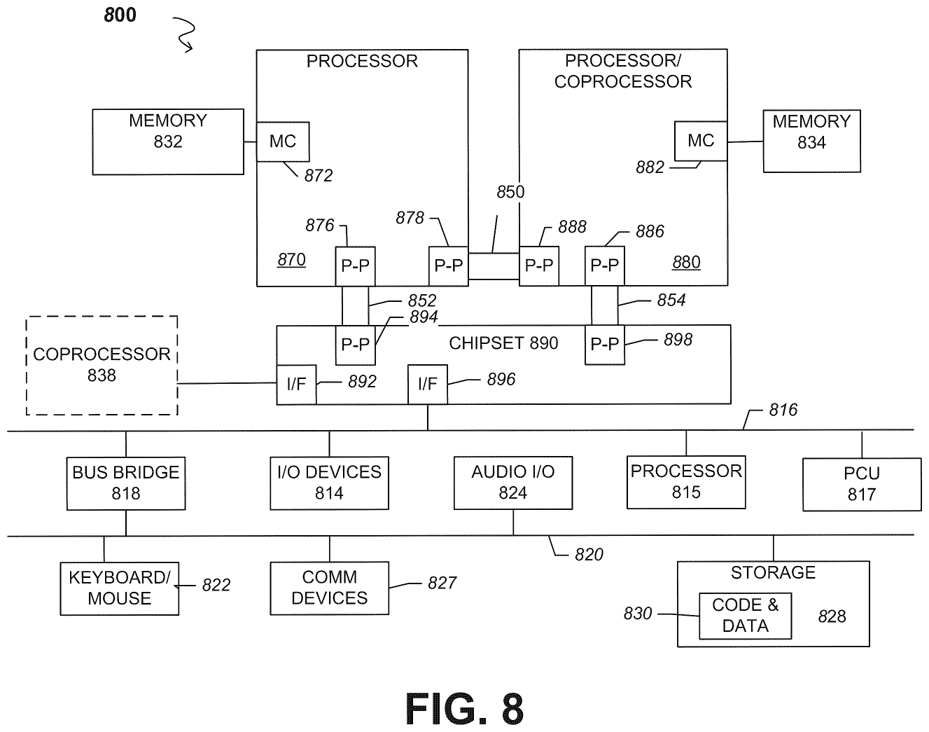

FIG. 8 illustrates an example computing system that incorporates one or more D2D links in accordance with embodiments disclosed herein. Multiprocessor system 800 is an interfaced system and includes a plurality of processors including a first processor 870 and a second processor 880 coupled via interfaces 850 such as point-to-point (P-P) interconnect, fabric, and/or bus interconnects, any of which may use physical inter-die connections implemented using Tx/Rx suppression circuitry as discussed herein. In some examples, the first processor 870 and the second processor 880 are homogeneous. In some examples, first processor 870 and the second processor 880 are heterogenous. Though the example system 800 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 870 and 880 are shown including memory controller (MC) circuitry 872 and 882, respectively. Processor 870 also includes interface circuits 876 and 878, along with core sets. Similarly, second processor 880 includes interface circuits 886 and 888, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 870, 880 may exchange information via the interface 850 using interface circuits 878, 888. IMCs 872 and 882 couple the processors 870, 880 to respective memories such as external memories, e.g., memories external to a common processor system package, namely a memory 832 and a memory 834, which may be portions of main memory attached to the respective processors.

Processors 870, 880 may each exchange information with a network interface (NW I/F) 890 via individual interfaces 852, 854 using interface circuits 876, 894, 886, 898. The network interface 890 (e.g., one or more of an interconnect, bus, and/or fabric, and in some examples is a chipset) may optionally exchange information with a coprocessor 838 via an interface circuit 892. In some examples, the coprocessor 838 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 870, 880 or outside of both processors, yet connected with the processors via an interface such as P-P interconnect, such that either or both processors' local cache information may be stored in the shared cache if a processor is placed into a low power mode.

Network interface 890 may be coupled to a first interface 816 via interface circuit 896. In some examples, first interface 816 may be an interface such as a Peripheral Component Interconnect (PCI) interconnect, a PCI Express interconnect, or another I/O interconnect. In some examples, first interface 816 is coupled to a power control unit (PCU) 817, which may include circuitry, software, and/or firmware to perform power management operations with regard to the processors 870, 880 and/or co-processor 838. PCU 817 provides control information to one or more voltage regulators (not shown) to cause the voltage regulator(s) to generate the appropriate regulated voltage(s). PCU 817 also provides control information to control the operating voltage generated. In various examples, PCU 817 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 817 is illustrated as being present as logic separate from the processor 870 and/or processor 880. In other cases, PCU 817 may execute on a given one or more of cores (not shown) of processor 870 or 880. In some cases, PCU 817 may be implemented as a microcontroller (dedicated or general-purpose) or other control logic configured to execute its own dedicated power management code, sometimes referred to as P-code. In yet other examples, power management operations to be performed by PCU 817 may be implemented externally to a processor, such as by way of a separate power management integrated circuit (PMIC) or another component external to the processor. In yet other examples, power management operations to be performed by PCU 817 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 814 may be coupled to first interface 816, along with a bus bridge 818 which couples first interface 816 to a second interface 820. In some examples, one or more additional processor(s) 815, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 816. In some examples, second interface 820 may be a low pin count (LPC) interface. Various devices may be coupled to second interface 820 including, for example, a keyboard and/or mouse 822, communication devices 827 and storage circuitry 828. Storage circuitry 828 may be one or more non-transitory machine-readable storage media as described below, such as a disk drive or other mass storage device which may include instructions/code and data 830 and may implement the storage in some examples. Further, an audio I/O 824 may be coupled to second interface 820. Note that other architectures than the point-to-point architecture described above are possible. For example, instead of the point-to-point architecture, a system such as multiprocessor system 800 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

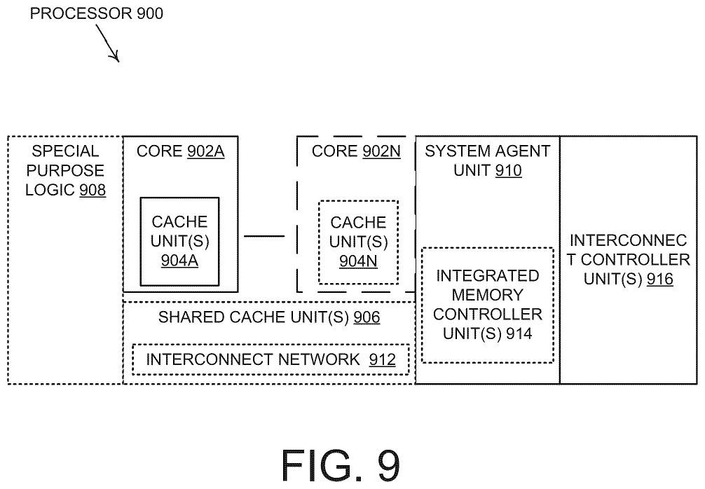

FIG. 9 illustrates a block diagram of an example processor and/or SoC 900 that may have one or more cores and an integrated memory controller. The solid lined boxes illustrate a processor 900 with a single core 902(A), system agent unit circuitry 910, and a set of one or more interface controller unit(s) circuitry 916, while the optional addition of the dashed lined boxes illustrates an alternative processor 900 with multiple cores 902(A)-(N), a set of one or more integrated memory controller unit(s) circuitry 914 in the system agent unit circuitry 910, and special purpose logic 908, as well as a set of one or more interface controller units circuitry 916. Note that the processor 900 may be one of the processors 870 or 880, or co-processor 838 or 815 of FIG. 8.

Thus, different implementations of the processor 900 may include: 1) a CPU with the special purpose logic 908 being integrated graphics and/or scientific (throughput) logic (which may include one or more cores, not shown), and the cores 902(A)-(N) being one or more general purpose cores (e.g., general purpose in-order cores, general purpose out-of-order cores, or a combination of the two); 2) a coprocessor with the cores 902(A)-(N) being a large number of special purpose cores intended primarily for graphics and/or scientific (throughput); and 3) a coprocessor with the cores 902(A)-(N) being a large number of general purpose in-order cores. Thus, the processor 900 may be a general-purpose processor, coprocessor or special-purpose processor, such as, for example, a network or communication processor, compression engine, graphics processor, GPGPU (general purpose graphics processing unit), a high throughput many integrated core (MIC) coprocessor (including 30 or more cores), embedded processor, or the like. The processor may be implemented on one or more chips. The processor 900 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 904(A)-(N) within the cores 902(A)-(N), a set of one or more shared cache unit(s) circuitry 906, and external memory (not shown) coupled to the set of integrated memory controller unit(s) circuitry 914. The set of one or more shared cache unit(s) circuitry 906 may include one or more mid-level caches, such as level 2 (L2), level 3 (L3), level 4 (L4), or other levels of cache, such as a last level cache (LLC), and/or combinations thereof. While in some examples interface network circuitry 912 (e.g., a ring interconnect) interfaces the special purpose logic 908 (e.g., integrated graphics logic), the set of shared cache unit(s) circuitry 906, and the system agent unit circuitry 910, alternative examples use any number of well-known techniques for interfacing such units. In some examples, coherency is maintained between one or more of the shared cache unit(s) circuitry 906 and cores 902(A)-(N). In some examples, interface controller units circuitry 916 couple the cores 902 to one or more other devices 918 such as one or more I/O devices, storage, one or more communication devices (e.g., wireless networking, wired networking, etc.), etc.

In some examples, one or more of the cores 902(A)-(N) are capable of multi-threading. The system agent unit circuitry 910 includes those components coordinating and operating cores 902(A)-(N). The system agent unit circuitry 910 may include, for example, power control unit (PCU) circuitry and/or display unit circuitry (not shown). The PCU may be or may include logic and components needed for regulating the power state of the cores 902(A)-(N) and/or the special purpose logic 908 (e.g., integrated graphics logic). The display unit circuitry is for driving one or more externally connected displays.

The cores 902(A)-(N) may be homogenous in terms of instruction set architecture (ISA). Alternatively, the cores 902(A)-(N) may be heterogeneous in terms of ISA; that is, a subset of the cores 902(A)-(N) may be capable of executing an ISA, while other cores may be capable of executing only a subset of that ISA or another ISA.

Illustrative examples of the technologies disclosed herein are provided below. An embodiment of the technologies may include any one or more, and any compatible combination of, the examples described below.

Example 1 is a circuit that includes a transmitter driver, a receiver, and a suppression circuit. The transmitter driver is coupled to a channel node to transmit data in a first direction onto the channel node. The receiver is coupled to the channel node to receive data from the channel node, the received data is to be in a second direction different from the first direction. The suppression circuit is coupled to the transmitter driver to suppress the transmitted data at an input of the receiver, and the suppression circuit has at least one variable resistor to tune the suppression circuit.

Example 2 includes the subject matter of example 1, and wherein the suppression circuit includes a first feedback resistor coupled between a feedback node and the channel node.

Example 3 includes the subject matter of any of examples 1-2, and wherein the suppression circuit includes a second feedback resistor coupled between the feedback node and an input to the transmitter driver, the feedback node being coupled to the receiver input.

Example 4 includes the subject matter of any of examples 1-3, and further comprises a filter resistor coupled between the feedback node and the receiver input.

Example 5 includes the subject matter of any of examples 1-4, and further comprises a capacitor coupled in parallel across at least one of the first and second feedback resistors.

Example 6 includes the subject matter of any of examples 1-5, and wherein the transmitter driver is a variable strength driver.

Example 7 includes the subject matter of any of examples 1-6, and comprising a pre-driver coupled between an input of the transmitter driver and a data input node.

Example 8 includes the subject matter of any of examples 1-7, and wherein the suppression circuit includes a pre-driver resistor coupled between the transmitter driver input and the data input node.

Example 9 includes the subject matter of any of examples 1-8, and wherein the pre-driver resistor is a variable resistor.

Example 10 includes the subject matter of any of examples 1-9, and wherein the channel node is part of a single-ended channel line.

Example 11 is an integrated circuit (IC) apparatus that includes first and second IC dies and a plurality of die-to-die (D2D) channel links coupled to the first and second dies to communicatively couple them together. Each link includes: (i) a first Tx/Rx circuit coupled to the first die, (ii) a second Tx/Rx circuit coupled to the second die, and (iii) a single-ended wire coupled between the first Tx/Rx circuit and the second Tx/Rx circuit, wherein each of the first and second Tx/Rx circuits includes an associated suppression circuit.

Example 12 includes the subject matter of example 11, and wherein the first die includes a first clock generator to provide a first clock coupled to the second die to clock receivers from the second Tx/Rx circuits, and the second die includes a second clock generator to provide a second clock coupled to the first die to clock receivers from the first Tx/Rx circuits, the first and second clocks being independent from one another.

Example 13 includes the subject matter of any of examples 11-12, and wherein each of the first and second Tx/Rx circuits include a transmitter driver, and the suppression circuits each include first and second feedback resistors coupled together between an input and an output of the transmitter driver, the first and second feedback resistors being coupled to each other at a common feedback node.

Example 14 includes the subject matter of any of examples 11-13, and wherein each of the first and second Tx/Rx circuits has a receiver with an input that is coupled to the common feedback node of its associated suppression circuit.

Example 15 includes the subject matter of any of examples 11-14, and comprising a filter resistor coupled between the common feedback node and the receiver input.

Example 16 includes the subject matter of any of examples 11-15, and comprising a capacitor coupled in parallel across at least one of the first and second feedback resistors.

Example 17 includes the subject matter of any of examples 11-16, and wherein each Tx/Rx circuit includes a pre-driver having a data input and an output coupled to the transmitter driver input for its Tx/Rx circuit.

Example 18 includes the subject matter of any of examples 11-17, and comprising a pre-driver resistor coupled between the data input and pre-driver output, the pre-driver resistor being a variable resistor.

Example 19 includes the subject matter of any of examples 11-18, and wherein each single-ended wire is implemented with a D2D line in a multi-chip substrate.

Example 20 includes the subject matter of any of examples 11-19, and wherein each single-ended wire is part of a bridge that is mounted to the substrate.

Example 21 includes the subject matter of any of examples 11-20, and wherein each single-ended wire is free of a termination resistor.

Example 22 is an integrated circuit package having first and second processor dies coupled together through a die-to-die interconnect that includes a plurality of bi-directional channel links coupled to the first and second processor dies. Each link includes (i) a first Tx/Rx circuit coupled to the first processor die, (ii) a second Tx/Rx circuit coupled to the second processor die, and (iii) a single-ended wire coupled between the first Tx/Rx circuit and the second Tx/Rx circuit, wherein each of the first and second Tx/Rx circuits includes an associated suppression circuit. Also included is an external memory coupled to the integrated circuit package.

Example 23 includes the subject matter of example 22, and wherein the first die includes a first clock generator to provide a first clock coupled to the second die to clock receivers from the second Tx/Rx circuits, and the second die includes a second clock generator to provide a second clock coupled to the first die to clock receivers from the first Tx/Rx circuits, the first and second clocks being independent from one another.

Example 24 includes the subject matter of any of examples 22-23, and wherein each of the first and second Tx/Rx circuits include a transmitter driver, and the suppression circuits each include first and second feedback resistors coupled together between an input and an output of the transmitter driver, the first and second feedback resistors being coupled to each other at a common feedback node.

Example 25 includes the subject matter of any of examples 22-24, and wherein each of the first and second Tx/Rx circuits has a receiver with an input that is coupled to the common feedback node of its associated suppression circuit.

Example 26 includes the subject matter of any of examples 22-25, and further comprising a filter resistor coupled between the common feedback node and the receiver input.

Example 27 includes the subject matter of any of examples 22-26, and further comprising a capacitor coupled in parallel across at least one of the first and second feedback resistors.

Example 28 includes the subject matter of any of examples 22-27, and wherein each Tx/Rx circuit includes a pre-driver having a data input and an output coupled to the transmitter driver input for its Tx/Rx circuit.

Example 29 includes the subject matter of any of examples 22-28, and comprising a pre-driver resistor coupled between the data input and pre-driver output, the pre-driver resistor being a variable resistor.

Example 30 includes the subject matter of any of examples 22-29, and wherein each single-ended wire is implemented with a D2D line in a multi-chip substrate.

Example 31 includes the subject matter of any of examples 22-30, and wherein each single-ended wire is part of a bridge that is mounted to the substrate.

Example 32 is a link apparatus that includes a plurality of simultaneous, bi-directional single-ended data channels. The channels each have first and second ends. The link apparatus also includes a plurality of first Tx/Rx circuits with associated hybrid circuits coupled to the first ends, a plurality of second Tx/Rx circuits with associated hybrid circuits coupled to the second ends, a first clock channel coupled to the plurality of second Tx/Rx circuits to provide a first clock to receivers in the plurality of second Tx/Rx circuits, and a second clock channel coupled to the plurality of first Tx/Rx circuits to provide a second clock to receivers in the plurality of first Tx/Rx circuits, wherein the first and second clocks are decoupled from each other.

Example 33 includes the subject matter of example 32, and wherein the hybrid circuits include at least one variable resistor to tune an associated Tx/Rx circuit.

Example 34 includes the subject matter of any of examples 32-33, and wherein the single-ended data channels are short-reach channels in a die-to-die interconnect.

Example 35 includes the subject matter of any of examples 32-34, and wherein the single-ended data channels are free of termination resistors.

Example 36 is an IC package having a link apparatus in accordance with any of examples 32-35 to communicatively couple together a first die with a second die.

Example 37 includes the subject matter of example 36, and wherein the first and second dies are processor chips forming at least part of a processor system.

Example 38 includes the subject matter of any of examples 32-37, and wherein the hybrid circuits include first and second series-coupled feedback resistors coupled together at a common feedback node, the series-coupled resistors being coupled between input and output nodes of a transmitter driver in the associated Tx/Rx circuit.

Example 39 includes the subject matter of any of examples 32-38, and wherein the hybrid circuits include a filter resister coupled between the common feedback node and an input node of a receiver in the associated Tx/Rx circuit.

Example 40 includes the subject matter of any of examples 32-39, and wherein the Tx/Rx circuits include variable strength transmitter drivers.

Example 41 includes the subject matter of any of examples 32-40, and wherein the Tx/Rx circuits include a pre-driver having a data input and an output coupled to an input of the variable strength transmitter driver.

Example 42 includes the subject matter of any of examples 32-41, and wherein the Tx/Rx circuits each include a receiver having a latch comparator.

Example 43 includes the subject matter of any of examples 32-42, and wherein the latch comparator has an adjustable threshold level.

Example 44 includes the subject matter of any of examples 32-43, and wherein the receiver latches in the plurality of second Tx/Rx circuits are clocked with the first clock and is supplied with a voltage supply different from the receivers in the plurality of first Tx/Rx circuits.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors, or other transistor device types such as carbon nanotubes or spintronic devices.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are dependent upon the platform within which the present disclosure is to be implemented.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth.

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. A circuit, comprising:
a transmitter driver coupled to a channel node to transmit data in a first direction onto the channel node;
a receiver coupled to the channel node to receive data from the channel node, the received data to be in a second direction different from the first direction; and
a suppression circuit coupled to the transmitter driver to suppress the transmitted data at an input of the receiver, the suppression circuit having at least one variable resistor to tune the suppression circuit.

2. The circuit of claim 1, wherein the suppression circuit includes a first feedback resistor coupled between a feedback node and the channel node.

3. The circuit of claim 2, wherein the suppression circuit includes a second feedback resistor coupled between the feedback node and an input to the transmitter driver, the feedback node being coupled to the receiver input.

4. The circuit of claim 3, further comprising a filter resistor coupled between the feedback node and the receiver input.

5. The circuit of claim 3, comprising a capacitor coupled in parallel across at least one of the first and second feedback resistors.

6. The circuit of claim 1, wherein the transmitter driver is a variable strength driver.

7. The circuit of claim 1, comprising a pre-driver coupled between an input of the transmitter driver and a data input node.

8. The circuit of claim 7, wherein the suppression circuit includes a pre-driver resistor coupled between the transmitter driver input and the data input node.

9. The circuit of claim 8, wherein the pre-driver resistor is a variable resistor.

10. The circuit of claim 1, wherein the channel node is part of a single-ended channel line.

11. An integrated circuit (IC) apparatus, comprising:
first and second IC dies; and
a plurality of die-to-die (D2D) channel links coupled to the first and second dies to communicatively couple them together, wherein each link includes:
(i) a first transmitter/receiver (Tx/Rx) circuit coupled to the first die,
(ii) a second Tx/Rx circuit coupled to the second die, and
(iii) a single-ended wire coupled between the first Tx/Rx circuit and the second Tx/Rx circuit, wherein each of the first and second Tx/Rx circuits includes an associated suppression circuit.

12. The apparatus of claim 11, wherein the first die includes a first clock generator to provide a first clock coupled to the second die to clock receivers from the second Tx/Rx circuits, and the second die includes a second clock generator to provide a second clock coupled to the first die to clock receivers from the first Tx/Rx circuits, the first and second clocks being independent from one another.

13. The apparatus of claim 11, wherein each of the first and second Tx/Rx circuits include a transmitter driver, and the suppression circuits each include first and second feedback resistors coupled together between an input and an output of the transmitter driver, the first and second feedback resistors being coupled to each other at a common feedback node.

14. The apparatus of claim 13, wherein each of the first and second Tx/Rx circuits has a receiver with an input that is coupled to the common feedback node of its associated suppression circuit.

15. The apparatus of claim 14, comprising a filter resistor coupled between the common feedback node and the receiver input.

16. The apparatus of claim 14, comprising a capacitor coupled in parallel across at least one of the first and second feedback resistors.

17. A system, comprising:
an integrated circuit package having first and second processor dies coupled together through a die-to-die interconnect comprising a plurality of bi-directional channel links coupled to the first and second processor dies, wherein each link includes:
(i) a first transmitter/receiver (Tx/Rx) circuit coupled to the first processor die,
(ii) a second Tx/Rx circuit coupled to the second processor die, and
(iii) a single-ended wire coupled between the first Tx/Rx circuit and the second Tx/Rx circuit, wherein each of the first and second Tx/Rx circuits includes an associated suppression circuit; and
external memory coupled to the integrated circuit package.

18. The system of claim 17, wherein the first die includes a first clock generator to provide a first clock coupled to the second die to clock receivers from the second Tx/Rx circuits, and the second die includes a second clock generator to provide a second clock coupled to the first die to clock receivers from the first Tx/Rx circuits, the first and second clocks being independent from one another.

19. The system of claim 17, wherein each single-ended wire is implemented with a D2D line in a multi-chip substrate.

20. The system of claim 19, wherein each single-ended wire is part of a bridge that is mounted to the substrate.
